(19) United States
(12) Patent Application Publication
(10) Pub. No.: US 2008/0089031 A1
(43) Pub. Date: Apr. 17, 2008

(54) Heat sink assembly

(75) Inventors: Jeng-Da Wu, Tu-Cheng (TW); Chih-Hang Chao, Tu-Cheng (TW); Yu-Hsu Lin, San Jose, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,883

(22) Filed: Oct. 17, 2006

(51) Int. Cl. H05K 7/20

(52) U.S. Cl. 361/719

(57) ABSTRACT

A heat sink assembly includes a printed circuit board, a chip mounted on a top surface of the board, and a heat sink attached onto the chip of the board. The heat sink includes a base, a plurality of fins extending up from the base, and a plurality of legs extending down from the base. The legs of the heat sink contact the top surface of the board to support the heat sink.

### FIELD OF THE INVENTION

The present invention relates to a heat sink assembly, and more particularly to a heat sink assembly which effectively protects a computer chip from damage and unstableness.

### DESCRIPTION OF RELATED ART

Due to the development of microelectronics technology, electronic devices now process data at unprecedented high speeds, producing large amounts of heat. To keep the system from becoming unstable or being damaged by the heat, the heat must be efficiently removed. Therefore, heat sinks are frequently used to dissipate heat from these electronic devices.

Conventionally, a heat sink is attached to an electronic device such as a central processing unit (CPU) by a clip. The clip is usually formed from steel. A usual heat sink clip assembly, includes a clip having a pair of legs spaced apart at their first ends by a contiguous connecting member which is pressed against the heat sink. At present, because of environmental considerations, the solder which is used to solder the electronic devices is lead-free, and the lead-free solder is more frangible than that including lead. When receiving different kinds of force, the lead-free solder attached on the electronic devices is easily damaged. Further, the electronic device under the heat sink receives a lot of pressure because of the clip pressing the heat sink, which may make the electronic device unstable.

Thus, an improved heat sink assembly which overcomes the above problems is desired.

### SUMMARY OF THE INVENTION

A heat sink assembly comprises a PCB, a chip mounted on a top surface of the PCB; and a heat sink attached to the chip of the PCB, The heat sink comprises a base supported on the chip, a plurality of fins extending up from the base, and a plurality of legs extending down from the base to contact the top surface of the PCB and support the heat sink.

Other advantages and novel features will be drawn from the following detailed description of preferred embodiments with attached drawings, in which:

### BRIEF DESCRIPTION OF THE DRAWINGS

FIG. 1 is an isometric view of a heat sink assembly in accordance with a preferred embodiment of the present invention;

FIG. 2 is a sectional view of the heat sink assembly of FIG. 1;

FIG. 3 is an isometric view of a heat sink assembly in accordance with another preferred embodiment of the present invention; and

FIG. 4 is a sectional view of the heat sink assembly of FIG. 3.

### DETAILED DESCRIPTION OF THE INVENTION

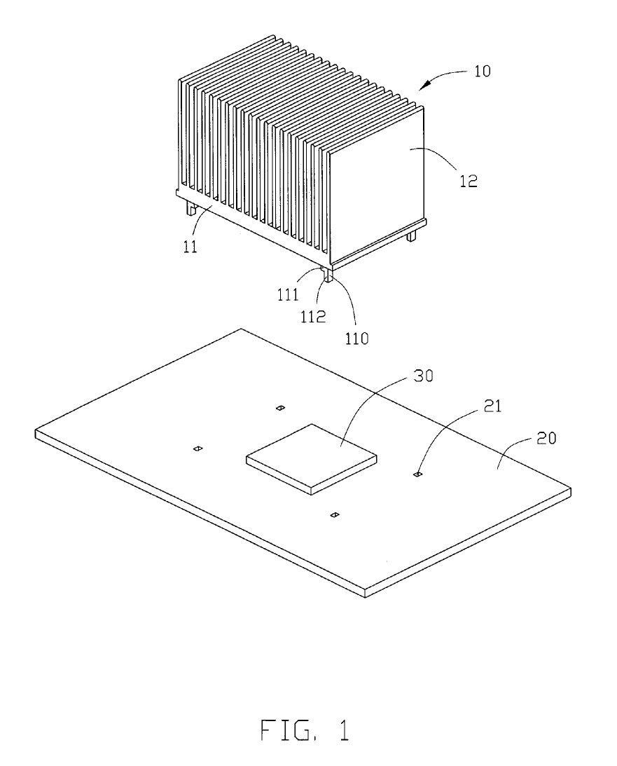

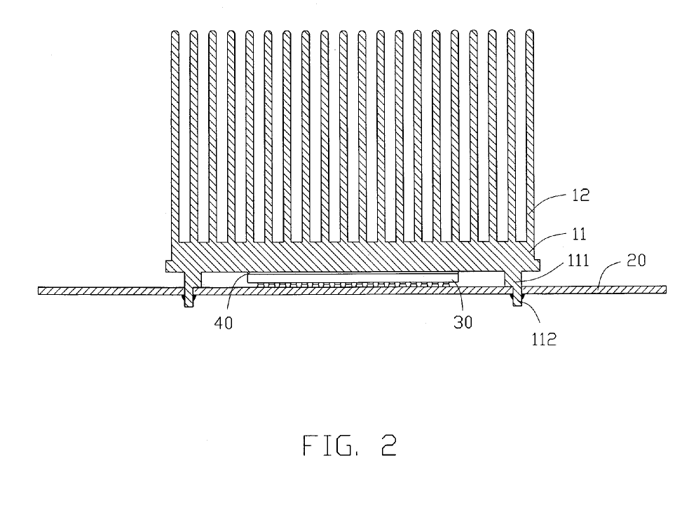

Referring to FIGS. 1 and 2, a heat sink assembly comprises a heat sink 1 0, a PCB 20, and a chip 30 attached on the PCB 20.

The heat sink 10 comprises a base 11, a plurality of fins 12 extending up from the base 11, and four legs 110 extending down from four corners of the base 11. Each leg 110 is in a ladder shape, including a supporting portion 111 with a large cross section, and an inserting portion 112 with a small cross section, which extends down from the supporting portion 111. The PCB 20 defines four holes 21 corresponding to the four legs 110 of the heat sink 10 respectively. A cross section of each of the holes 21 is larger than that of the inserting portion 112 but smaller than that of the supporting portion 111 to stop the supporting portion 111 passing through the holes 21. An upright length of the supporting portion 112 is greater than a thickness of the chip 30. The chip 30 is attached on the PCB 20 among the four holes 21. A layer of a heat-conduction medium 40 is disposed on a top surface of the chip 30.

In assembly of the heat sink 10 onto the PCB 20, the inserting portions 112 of the heat sink 10 are inserted in the holes 21 of the PCB 20 respectively until the supporting portions 111 resist the top surface of the PCB 20, and the heat sink 10 is compressing the layer of heat-conduction medium 40. Because the supporting portions 111 contact on the PCB 20, pressure from the heat sink 10 is distributed between the chip 30 and the PCB 20, protecting the chip 30. The parts of the inserting portions 112 that pass through the holes 21 may be fastened to the bottom surface of the PCB 20, by soldering, gluing, and so on.

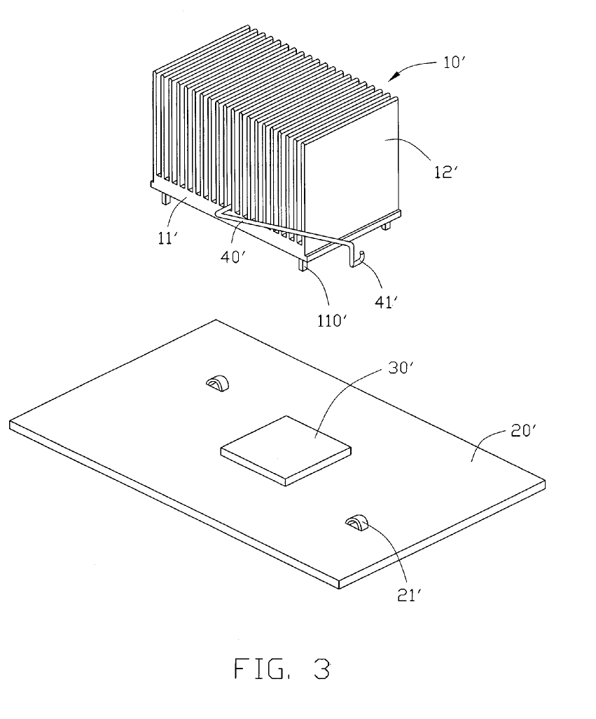

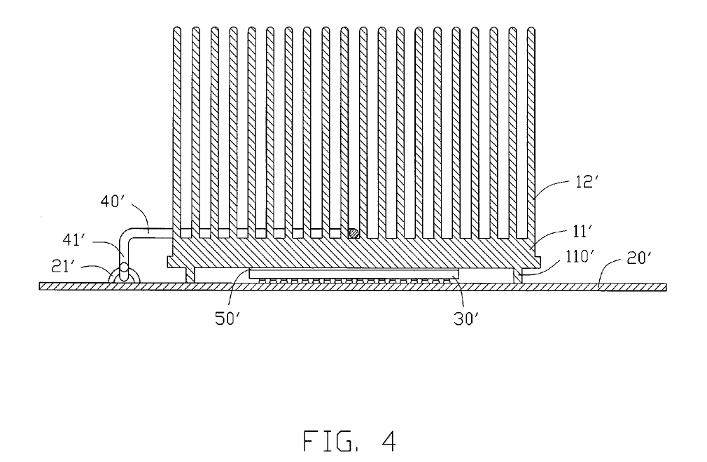

Referring to FIGS. 3 and 4, in another preferred embodiment of the present invention. A heat sink 10′ is used in heat dissipation of a chip 30′ which is attached on a PCB 20′.

The heat sink 110′ comprises a base 11′, a plurality of fins 12′ extending up from the base 11′, and four legs 110′ extending down from the base 11′. A layer of heat-conduction medium 50′ is disposed on a top surface of the chip 30′. The upright length of the leg 110′ is greater than that of the chip 30′. The heat sink clip 40′ defines two latching members 41′ at the end of the heat sink clip 40′. The PCB 20′ defines two latching rings 21′ corresponding to the latching members 41′.

In assembling the heat sink 10′ onto the PCB 20′, the heat sink 10′ is laid on the PCB 20′, compressing the layer of heat-conduction medium 50′. Distal ends of the legs 110′ away from the base 11′ contact the top surface of the PCB 20′. Because the legs 110′ contact on the PCB 20′, pressure from the heat sink 10′ is distributed between the chip 30′ and the PCB 20′, protecting the chip 30′. Then, the heat sink clip 40′ is mounted on the base 11′ of the heat sink 10′ and the latching members 41′ clasp the latching rings of the PCB 20′. Thus, the heat sink 10 is fastened on the PCB 20′, as best shown in FIG. 4.

In the above embodiments of the present invention, the legs may be of greater number and have different shapes. The PCB may define a plurality of flutes corresponding to the legs of the heat sink. The legs of the heat sink may be formed separately then connected to the heat sink.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

1. A heat sink assembly, comprising:
a printed circuit board defining a plurality of holes therein;
a chip attached on a top surface of the board; and
a heat sink attached on the chip, the heat sink having a base, a plurality of fins extending up from the base, and a plurality of legs extending down from the base corresponding to the holes of the board, each leg being integral and comprising a supporting portion extending directly from the base and an inserting portion extending from the supporting portion;
wherein the inserting portions of the legs insert into the holes of the board with the supporting portions resisting on the top surface of the board to support the heat sink on the board;
wherein the heat sink is secured on the board with a heat sink clip.

2. The heat sink assembly as described in claim 1, wherein the cross sections of the supporting portions are greater than those of the inserting portions.

3. The heat sink assembly as described in claim 1, wherein there is a layer of heat-conduction medium disposed between the chip and the base of the heat sink.

4-5. (canceled)

6. A heat sink assembly, comprising:
a printed circuit board;
a chip attached on a top surface of the board;
a heat sink clip; and
a heat sink mounted on the board, the heat sink having a base thermally contacting the chip, a plurality of fins extending up from a side of the base, and a plurality of legs integrally extending down from an opposite side of the base;
wherein the legs of the heat sink contacting the top surface of the board to support the heat sink on the board;
wherein the heat sink is secured on the printed circuit board by the heat sink clip, the heat sink clip comprising a shaft portions parallel to the fins and the base of the heat sink, and a pair of resilient arms extending from two ends of the shaft portion in opposite directions, each of arms comprising a latching member at a distal end thereof: the latching members being located at diagonal corners of the heat sink, and the board comprises two latching rings thereon engaging with the latching members of the heat sink cup.

7-9. (canceled)

10. The heat sink assembly as described in claim 6, wherein there is a layer of heat-conduction medium disposed between the chip and the base of the heat sink.

11-14. (canceled)

15. The heat sink assembly as described in claim 1, wherein the heat sink clip comprises a shaft portion parallel to the fins and straddling over the heat sink, and a pair of resilient arms extending from opposite ends of the shaft portion in opposite directions, the pair of arms comprising a pair of latching members at the ends thereof respectively to locate the pair of latching members at the diagonal corners of the heat sink, and the board comprises two latching rings thereon engaging with the latching members of the heat sink clip.
